(19) United States
(12) Patent Application Publication
(10) Pub. No.: US 2017/0247248 A1
(43) Pub. Date: Aug. 31, 2017

(54) INTEGRATED MEMS TRANSDUCER AND CIRCUITRY

(71) Applicant: Cirrus Logic International Semiconductor Ltd., Edinburgh (GB)

(72) Inventor: Tsjerk Hans HOEKSTRA, Balerno (GB)

(73) Assignee: Cirrus Logic International Semiconductor Ltd., Edinburgh (GB)

(21) Appl. No.: 15/440,525

(22) Filed: Feb. 23, 2017

Related U.S. Application Data
(60) Provisional application No. 62/301,076, filed on Feb. 29, 2016.

(30) Foreign Application Priority Data
Mar. 31, 2016 (GB) 1605478.5

(51) Int. Cl. B81B 7/00; H04R 1/04; B81C 1/00

(52) U.S. Cl. CPC B81B 7/008; B81C 1/00246; H04R 1/04; B81B 2207/07; B81B 2207/015; B81B 2203/0127; B81B 2201/0257; B81C 2203/0735; H04R 2201/003; H04R 31/006

(57) ABSTRACT

The application relates to integrated MEMS transducers comprising a MEMS transducer structure formed of a plurality of transducer layers and at least one circuit component formed from a plurality of circuitry (CMOS) layers. The integrated MEMS transducer further comprises a conductive enclosure that is integral to the transducer layers and circuitry layers. The at least one circuit component is inside the conductive enclosure whilst the MEMS transducer structure is outside the enclosure.

This invention relates to integrated MEMS transducers having a MEMS transducer structure integrated with associated circuitry on a monolithic die, and to methods of fabricating such integrated MEMS transducers.

### BACKGROUND

Consumer electronics devices are continually getting smaller and, with advances in technology, are gaining increasing performance and functionality. This is clearly evident in the technology used in consumer electronic products such as mobile phones, laptop computers, MP3 players and personal digital assistants (PDAs). Requirements of the mobile phone industry for example, are driving the components to become smaller, yet with higher functionality and reduced cost. It is therefore desirable to integrate functions of electronic circuits together and combine them with transducer devices such as microphones and speakers.

The result of this is the emergence of micro-electrical-mechanical-systems (MEMS) based transducer devices. These may be for example, capacitive transducers for detecting and/or generating pressure/sound waves or transducers for detecting acceleration. There is a continual drive to reduce the size and cost of these devices through integration with the electronic circuitry necessary to operate and process the information from the MEMS through the removal of the transducer-electronic interfaces. One of the challenges in reaching these goals is the difficulty of achieving compatibility with standard processes used to fabricate complementary-metal-oxide-semiconductor (CMOS) electronic devices during manufacture of MEMS devices. This is required to allow integration of MEMS devices directly with conventional electronics using the same materials and processing machinery. This invention seeks to address this area.

Microphone devices formed using MEMS fabrication processes typically comprise one or more membranes with electrodes for read-out/drive deposited on the membranes and/or a substrate. In the case of MEMS pressure sensors and microphones, the read out is usually accomplished by measuring the capacitance between a pair of electrodes which will vary as the distance between the electrodes changes in response to sound waves incident on the membrane surface.

FIGS. 1a and 1b show a schematic diagram and a perspective view, respectively, of a known capacitive MEMS microphone device 100. The capacitive microphone device 100 comprises a membrane layer 101 which forms a flexible membrane which is free to move in response to pressure differences generated by sound waves. A first electrode 102 is mechanically coupled to the flexible membrane, and together they form a first capacitive plate of the capacitive microphone device. A second electrode 103 is mechanically coupled to a generally rigid structural layer or back-plate 104, which together form a second capacitive plate of the capacitive microphone device. In the example shown in FIG. 1a the second electrode 103 is embedded within the back-plate structure 104.

The capacitive microphone is formed on a substrate 105, for example a silicon wafer which may have upper and lower oxide layers 106, 107 formed thereon. A cavity 108 in the substrate and in any overlying layers (hereinafter referred to as a substrate cavity) is provided below the membrane, and may be formed using a “back-etch” through the substrate 105. The substrate cavity 108 connects to a first cavity 109 located directly below the membrane. These cavities 108 and 109 may collectively provide an acoustic volume thus allowing movement of the membrane in response to an acoustic stimulus. Interposed between the first and second electrodes 102 and 103 is a second cavity 110.

The first cavity 109 may be formed using a first sacrificial layer during the fabrication process, i.e. using a material to define the first cavity which can subsequently be removed, and depositing the membrane layer 101 over the first sacrificial material. Formation of the first cavity 109 using a sacrificial layer means that the etching of the substrate cavity 108 does not play any part in defining the diameter of the membrane. Instead, the diameter of the membrane is defined by the diameter of the first cavity 109 (which in turn is defined by the diameter of the first sacrificial layer) in combination with the diameter of the second cavity 110 (which in turn may be defined by the diameter of a second sacrificial layer). The diameter of the first cavity 109 formed using the first sacrificial layer can be controlled more accurately than the diameter of a back-etch process performed using a wet-etch or a dry-etch. Etching the substrate cavity 108 will therefore define an opening in the surface of the substrate underlying the membrane 101.

A plurality of holes, hereinafter referred to as bleed holes 111, connect the first cavity 109 and the second cavity 110.

As mentioned the membrane may be formed by depositing at least one membrane layer 101 over a first sacrificial material. In this way the material of the membrane layer(s) may extend into the supporting structure, i.e. the side walls, supporting the membrane. The membrane and back-plate layer may be formed from substantially the same material as one another, for instance both the membrane and back-plate may be formed by depositing silicon nitride layers. The membrane layer may be dimensioned to have the required flexibility whereas the back-plate may be deposited to be a thicker and therefore more rigid structure. Additionally various other material layers could be used in forming the back-plate 104 to control the properties thereof. The use of a silicon nitride material system is advantageous in many ways, although other materials may be used, for instance MEMS transducers using polysilicon membranes are known.

In some applications, the microphone may be arranged in use such that incident sound is received via the back-plate. In such instances a further plurality of holes, hereinafter referred to as acoustic holes 112, are arranged in the back-plate 104 so as to allow free movement of air molecules, such that the sound waves can enter the second cavity 110. The first and second cavities 109 and 110 in association with the substrate cavity 108 allow the membrane 101 to move in response to the sound waves entering via the acoustic holes 112 in the back-plate 104. In such instances the substrate cavity 108 is conventionally termed a “back volume”, and it may be substantially sealed.

In other applications, the microphone may be arranged so that sound may be received via the substrate cavity 108 in use. In such applications the back-plate 104 is typically still provided with a plurality of holes to allow air to freely move between the second cavity and a further volume above the back-plate.

It should also be noted that whilst FIG. 1 shows the back-plate 104 being supported on the opposite side of the membrane to the substrate 105, arrangements are known where the back-plate 104 is formed closest to the substrate with the membrane layer 101 supported above it.

In use, in response to a sound wave corresponding to a pressure wave incident on the microphone, the membrane is deformed slightly from its equilibrium position. The distance between the lower electrode 102 and the upper electrode 103 is correspondingly altered, giving rise to a change in capacitance between the two electrodes that is subsequently detected by electronic circuitry (not shown). The bleed holes allow the pressure in the first and second cavities to equalise over a relatively long timescales (in acoustic frequency terms) which reduces the effect of low frequency pressure variations, e.g. arising from temperature variations and the like, but without impacting on sensitivity at the desired acoustic frequencies.

The transducer shown in FIG. 1 is illustrated with substantially vertical side walls supporting the membrane layer 101 in spaced relation from the back-plate 104. Given the nature of the deposition process this can lead to a high stress concentration at the corners formed in the material layer that forms the membrane. Sloped or slanted side walls may be used to reduce the stress concentration. Additionally or alternatively it is known to include a number of support structures such as columns to help support the membrane in a way which reduces stress concentration. Such columns are formed by patterning the first sacrificial material used to define the first cavity 109 such that the substrate 105 is exposed in a number of areas before depositing the material forming the membrane layer 101. However, this process can lead to dimples in the upper surface of the back-plate layer in the area of the columns.

It will be appreciated that, in order to incorporate the transducers into useful devices, it is necessary to interface or couple them to electronic circuitry.

As shown in FIG. 1 the membrane electrode 104 and back-plate electrode 108 are typically connected via tracks (not shown) to contact pads 116 and 118 respectively for connection to electronic circuitry. The tracks are formed during deposition and patterning of the relevant electrode and provide a connection from the electrode to a contact area a short distance away from the structure of the transducer. The conducting tracks are buried in subsequent deposition stages. Part of the fabrication process involves etching holes down to the end of the tracks and filling with conductive material to provide conductive vias. The top of the conductive vias are covered with the contact pads for connection to the electronic circuitry.

The circuitry may conveniently be CMOS (complementary-metal-oxide-on-semiconductor) circuitry and thus comprise various CMOS layers. As the skilled person will appreciate CMOS circuitry is formed by depositing appropriate metal and inter-metal dielectric (IMD) or inter layer dielectric (ILD) materials over appropriately doped regions of the substrate.

Commonly, MEMS capacitive transducers are fabricated on a separate substrate to the electronics. Thus the contact pads 116 and 118 described above with reference to FIG. 1 are arranged as, or are electrically connected to, bond pads suitable for wire bonding to corresponding bond pads on a separate substrate carrying the electronic circuitry.

More recently, efforts have been focussed on integrating the electronic circuitry and the transducer onto a single substrate, so that the MEMS structure and associated circuity, e.g. biasing circuitry and/or amplifier circuitry, are fabricated on the same chip. This can have a number of benefits and advantages. For example the integration of a MEMS transducer with electronic circuity on the same substrate provides a reduction in size compared to a two-chip design. It also avoids the need for connections such as bond pads and wire bonds in the signal path between the MEMs transducer and the circuitry, which can introduce unwanted parasitic capacitances and/or inductances and resulting signal loss.

The electronic circuitry associated with operation of the transducer, e.g. biasing circuitry and/or amplifier circuitry, will typically comprise a plurality of transistors and interconnections. This circuitry may be fabricated by using standard integrated circuit processing techniques, for instance CMOS processing.

As mentioned above, MEMS transducers are increasingly being used in portable devices with communication capability, e.g. mobile telephones or the like. Such devices will include at least one antenna for transmitting RF signals. The amount of power transmitted by such devices can be relatively high and is set to increase with changes to the communication standards. This can cause a problem for MEMS transducers, such as microphones, with CMOS circuitry. The transmitted RF signals can be coupled to the CMOS circuitry and, as the CMOS circuitry is inherently non-linear, such signals may be demodulated to the audio band. This may therefore result in audible noise such as the so-called “bumblebee noise”. This problem may be exacerbated when using MEMS microphones with integrated CMOS circuitry as in many devices the position of the antenna happens to be close to the position where the microphone is required.

It is known for electromagnetic shielding to be provided so as to protect a MEMS transducer and associated circuitry from electromagnetic radiation, in particular radio frequency interference (RFI). Such shielding is typically provided as part of the “package”, or cover, which protects and encloses the integrated MEMS transducer. For example, U.S. Pat. No. 7,166,910, U.S. Pat. No. 5,740,251 and U.S. Pat. No. 6,324,907 each disclose MEMS transducer assembly designs which incorporate conductive material as part of the lid, or package, so as to protect the enclosed transducer against electromagnetic interferences. In this sense, the package incorporating conductive shielding can act in the manner of a Faraday shield, to protect the transducer and associated circuitry against external electromagnetic (EM) interference.

A Faraday shield, or Faraday cage, utilises an electrically conductive material as a way of blocking, or attenuating, electromagnetic fields. A Faraday shield is commonly used to protect sensitive electronic components from external EM interference, in particular from external Radio Frequency Interference (RFI). As will be appreciated, the shielding effect of a conductive enclosure arises because an external electromagnetic field causes the electric charges within the cage's conducting material to be distributed such that they cancel the field's effect in the cage's interior. The energy caused by the EM radiation that is coupled into a Faraday cage is dissipated as eddy current losses.

Although the shielding provided by the previously considered designs is useful at attenuating external RF radiation, difficulties in protecting circuitry from RFI still arise. This is particularly a problem when the transducer package is located relatively close to an RF antenna within a communication device due to the strength of the RF field arising from the antenna which may be insufficiently attenuated by the previously considered shielding techniques.

### SUMMARY

According to a first aspect of the present invention there is provided an integrated MEMS transducer comprising a MEMS transducer structure formed from a plurality of transducer layers and at least one circuit component formed from one or more circuitry layers, further comprising a conductive enclosure for attenuating electromagnetic radiation, wherein the conductive enclosure is formed from material comprised in a plurality of the transducer layers and/or the circuitry layers.

Thus, the conductive enclosure is formed of material that is deposited during the fabrication of the circuitry and/or during the fabrication of the MEMS transducer structure. As a result, the conductive enclosure forms an integral part of the integrated MEMS transducer. The conductive enclosure can be considered to be embedded within the structural layers of the integrated MEMS transducer.

According to a second aspect of the present invention there is provided an integrated MEMS transducer comprising a MEMS transducer structure formed from a plurality of transducer layers and at least one circuit component formed from one or more circuitry layers, further comprising a Faraday shield for attenuating RF radiation, the Faraday shield being formed of material comprised in one or more of the transducer layers.

Thus, the material that forms the eventual shield or enclosure will be deposited during the same processing steps that are carried out to form the integrated transducer. Thus, the conductive enclosure is efficiently fabricated in parallel to the fabrication of the circuitry layers and the transducer layers.

According to a further aspect of the present invention there is provided an integrated MEMS transducer comprising a MEMS transducer structure and at least one circuit component, the integrated MEMS transducer further comprising a conductive enclosure provided such that the at least one circuitry component is within the conductive enclosure, and wherein the MEMS transducer structure is outside the enclosure.

The MEMS transducer structure may be formed on a first region of a substrate and the at least one circuit component may be formed on a second region of the substrate. The circuitry may preferably comprise a plurality of CMOS layers. The CMOS layers typically comprise a plurality of dielectric layers and a plurality of metal layers. The transducer structure may be considered to comprise a plurality of transducer layers. Preferably, the transducer structure comprises a capacitive MEMS transducer comprising a moveable membrane having a membrane electrode and a back-plate having a back-plate electrode.

The conductive enclosure may comprise a top plate, formed of a metal/conductive layer, which overlies the circuitry or the first region of the substrate and acts in the manner of a Faraday shield to attenuate RF radiation. The top plate may be deposited during the deposition of one of the transducer layers, e.g. during the deposition of metal forming part of the transducer structure. The top plate may have a thickness that is greater than the thickness of one transducer layer e.g. the top plate be comprised of more than one layer of conductive material.

The conductive enclosure comprises a bottom plate that underlies the circuitry or the second region of the substrate. The bottom plate may comprise low resistance silicon, e.g. formed from a doped region of the silicon substrate, or a metal layer. Alternatively, the bottom plate may comprise an implant layer or a so-called “extra deep” implant layer formed e.g. by doping, within a deep well of the silicon substrate.

The conductive enclosure comprises at least one side wall which may be formed of a plurality of conductive vias which extend through one or more CMOS layers and serve to connect the top plate and the bottom plate. Thus, in a preferred embodiment the conductive enclosure comprises a top plate which overlies the circuitry and a bottom plate that underlies the circuitry, wherein the top plate and the bottom plate are connected by a plurality of conductive vias which extend through one or more layers of the integrated MEMS transducer to form side walls of the conductive enclosure and thereby to enclose the circuitry.

According to a further aspect of the present invention there is provided an integrated MEMS transducer comprising a MEMS transducer structure and circuitry provided on a single substrate/die, wherein the MEMS transducer is formed from a plurality of transducer layers and wherein at least one conductive layer deposited during the fabrication of the MEMS transducer structure forms a shield which overlies the circuitry for shielding the circuitry from electromagnetic radiation.

Preferably, the shield is electrically connected to a conductive layer which underlies the circuitry, thereby forming an electrically conductive enclosure around the circuitry.

The circuitry may comprise a plurality of CMOS layers and a plurality of conductive vias may be formed so as to extend through one or more CMOS layers from the underside of the shield to the underlying conductive layer, to form side walls of the conductive enclosure.

According to embodiments of the present invention the metal top plate may be formed during one or more of the metallisation steps carried out as part of the formation of the transducer structure.

According to a further aspect of the present invention there is provided an integrated MEMS transducer comprising, or incorporating, a conductive enclosure. Preferably, the conductive enclosure is formed from material comprised within the layers of the transducer structure and the circuitry structure (CMOS layers). Thus, the conductive enclosure is preferably formed from material deposited during the fabrication of the integrated MEMS transducer device.

According to a further aspect of the present invention there is provided an integrated MEMS transducer comprising a MEMS transducer structure formed of a plurality of transducer layers and at least one circuit component formed from a plurality of circuitry layers, wherein the integrated MEMS transducer further comprises a conductive enclosure that is integral to the transducer layers and circuitry layers. Preferably, the at least one circuit component is inside the conductive enclosure whilst the MEMS transducer structure is outside the enclosure.

According to a further aspect of the present invention there is provided an integrated MEMS transducer comprising a MEMS transducer structure formed from a plurality of transducer layers and at least one circuit component formed from one or more circuitry layers, further comprising a conductive enclosure which is embedded within the transducer layers and/or the circuitry layers so as to form an integral part of the integrate MEMS transducer.

According to a further aspect there is provided an integrated MEMS transducer comprising a MEMS transducer structure formed from a plurality of transducer layers and at least one circuit component formed from one or more circuitry layers, further comprising a Faraday shield for attenuating RF radiation, the Faraday shield being formed of material comprised in one or more of the transducer layers.

It will be appreciated that in the context of the present invention the term “walls” embraces not just a continuous plane of conductive material, but may also embrace a series of discrete columns or “castellation's”, which are preferably closely spaced. The present invention therefore conveniently provides a method that can be implemented using standard CMOS processing steps in a single standard CMOS foundry to produce an integrated transducer and electronics and further incorporating a shield or enclosure to protect the circuitry from RF radiation. Advantageously, all of the functional layers for the integrated MEMS transducer, including a conductive shield/enclosure for protecting the circuitry from RF radiation, can be fabricated as part of a CMOS process. This represents a more efficient solution from the perspective of manufacturing an integrated MEMS transducer, as compared to previously considered integrated transducer designs which incorporate conductive shielding material as part of the package or cover, since the fabrication of the enclosure/shield occurs in parallel with the fabrication of the device and results in electromagnetic shielding that is integral to the structure of the MEMS transducer and associated circuitry. In this sense, the protective Faraday shield/enclosure is formed during the wafer-level processing rather than at the package-level processing. This represents a more efficient and streamlined manner of fabricating a Faraday shield/enclosure to protect the circuitry components of an integrated MEMS transducer.

According to embodiments of the present invention the conductive enclosure forms a so-called Faraday cage. Due to the locality/proximity of the enclosure to the circuitry—in other words as a consequence of the shield/enclosure being an integral part of the integrated MEMS transducer which surrounds the circuitry components, it is possible to provide improved/greater attenuation of RFI. Thus, preferred embodiments of the present invention may protect the sensitive circuit components from external electromagnetic interference by attenuating electromagnetic radiation, even when the integrated transducer is to be located close to an antenna which acts as a source of RF radiation.

The transducer is a capacitive transducer and thus comprises a membrane electrode and a back-plate electrode. If a suitably conductive material is used for the membrane layer or back-plate layer then a single layer may provide the structure of the membrane/back-plate and also function as the electrode. Conveniently however there are a plurality of membrane layers, comprising at least one structural membrane layer and at least one membrane electrode layer, and a plurality of back-plate layers comprising at least one structural back-plate layer and at least one back-plate electrode layer.

The transducer is fabricated in a first area on the substrate and the at least one circuit component in a second area of the substrate. The transducer and the circuitry are thus formed at different parts of the substrate. Preferably the method involves forming the circuit layers, i.e. the at least one metal layer and the at least one dielectric layer, into a plurality of circuit components in the second area. The circuit components may be arranged to provide suitable circuitry for the MEMS transducer. Suitable circuitry may include, without limitation, amplifier circuitry, voltage biasing circuitry, filter circuitry, analogue to digital converters and/or digital to analogue converters, oscillator circuitry, voltage reference circuitry, current reference circuitry and charge pump circuitry.

The second area may be located in a distinct region of the substrate to the first region. For instance the transducer may be formed such that it is located on one side of the substrate and the circuitry may be located on the other side of the substrate. As used herein the term substrate is taken to refer to the final substrate of an individual device. The skilled person will appreciate that multiple devices are typically processed on a single wafer and ultimately diced into individual substrates.

According to a further aspect of the present invention there is provided a method of fabricating an integrated MEMS transducer comprising a MEMS transducer structure and at least one circuit component on a substrate, the method comprising: forming, on a first region of the substrate, a plurality of CMOS layers, wherein the at least one circuit component is formed from one or more of the CMOS layers; forming, on a second region of the substrate, a plurality of transducer layers to form the MEMS transducer structure; wherein said method comprises depositing a common layer of conductive material which forms a conductive layer of the MEMS transducer structure and also forms a top-plate which overlies the at least one circuit component, said top-plate being for shielding the circuitry from electromagnetic radiation.

In one embodiment, the method comprises the step of forming the dielectric and metal layers of the circuit layers prior to forming any of the transducer layers. The transducer layers are thus formed on top of the dielectric layers deposited in the first area during formation of the circuit layers. The transducer membrane is therefore arranged over a cavity formed in at least one of the CMOS layers. It will be clear therefore that the transducer in this embodiment is not fabricated directly on the surface of the substrate but on top of other layers deposited on the substrate. As used herein the step of forming a layer on the substrate includes forming such a layer on top of any intervening layers formed on the substrate.

The transducer may be a capacitive sensor such as a microphone. The transducer may comprise readout circuitry (analogue and/or digital). The transducer and circuitry may be provided together on a single semiconductor chip—e.g. an integrated microphone. Alternatively, the transducer may be on one chip and the circuitry may be provided on a second chip. The transducer may be located within a package having a sound port, i.e. an acoustic port. The transducer may be implemented in an electronic device which may be at least one of: a portable device; a battery powered device; an audio device; a computing device; a communications device; a personal media player; a mobile telephone; a tablet device; a games device; and a voice controlled device.

The MEMS capacitive transducers of the present invention may comprise sensing transducers such as a microphone and/or transmitting transducers such as loudspeakers. Where the apparatus comprises a plurality of transducers on the same substrate there may be one or transmitter and one or more receiver on the same substrate.

Features of any given aspect may be combined with the features of any other aspect and the various features described herein may be implemented in any combination in a given embodiment.

Associated methods of fabricating a MEMS transducer are provided for each of the above aspects.

### BRIEF DESCRIPTION OF THE DRAWINGS

For a better understanding of the present invention, and to show how the same may be carried into effect, reference will now be made by way of example to the accompanying drawings in which:

FIGS. 1a and 1b show a known capacitive MEMS transducer;

FIG. 2 shows an example cross section through some CMOS circuitry layers according to a typical CMOS process;

FIG. 3 illustrates an integrated MEMS transducer according to one embodiment of the present invention;

FIG. 4 illustrates a possible arrangement of conductive vias forming a side wall of a conductive enclosure according to an embodiment of the present invention; and

FIGS. 5a, 5b, and 5c illustrate an integrated MEMS transducer according to another embodiment of the present invention and incorporating several alternative bottom plate designs.

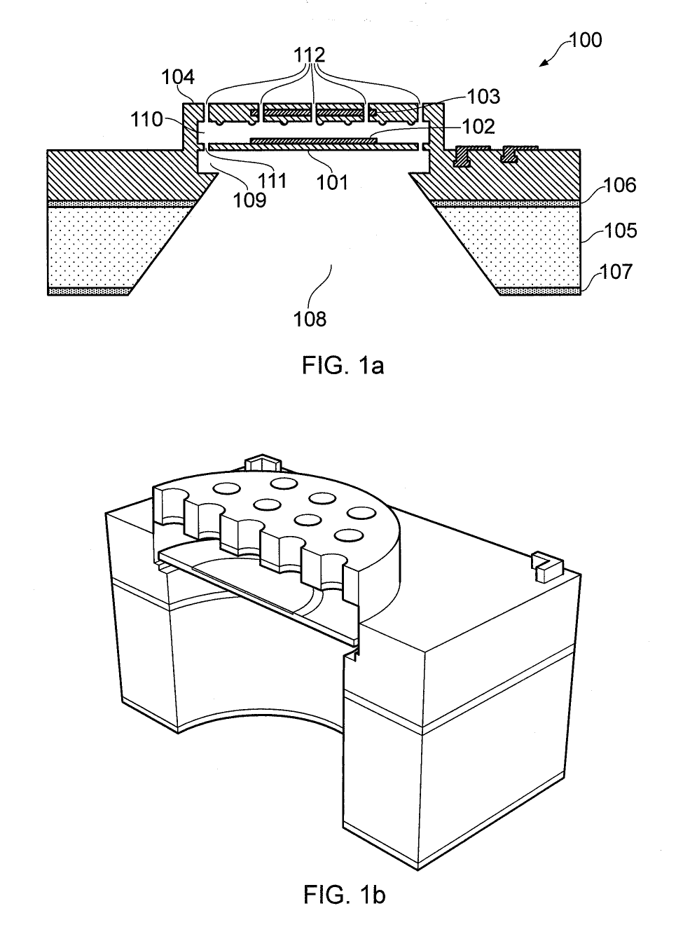

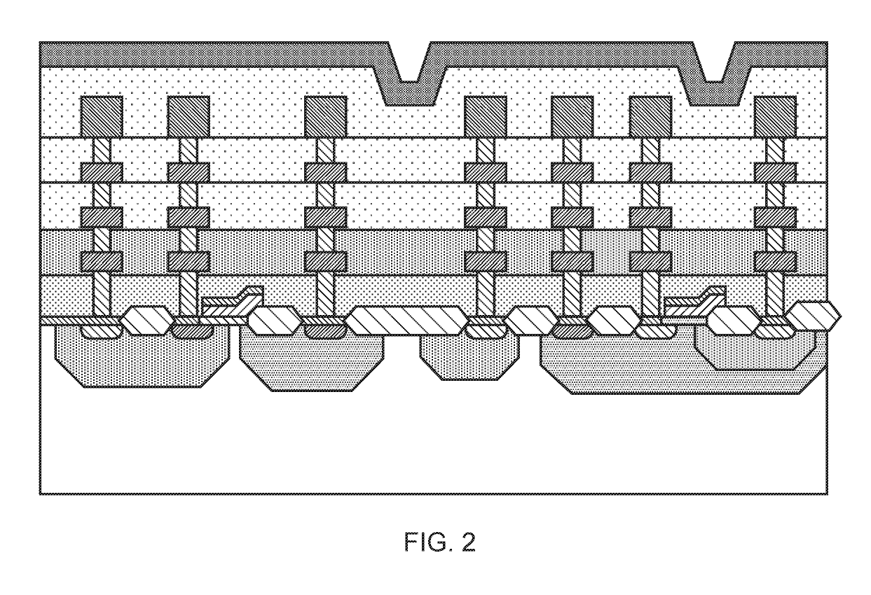

### DESCRIPTION

The examples described below will be described in relation to the integration of a MEMS microphone with CMOS circuitry. However, it will be appreciated that the general teaching applies to a variety of other MEMS transducers, including loudspeakers and pressure sensors as well as any other MEMS transducer incorporating at least one circuit component that is integrated on a single die.

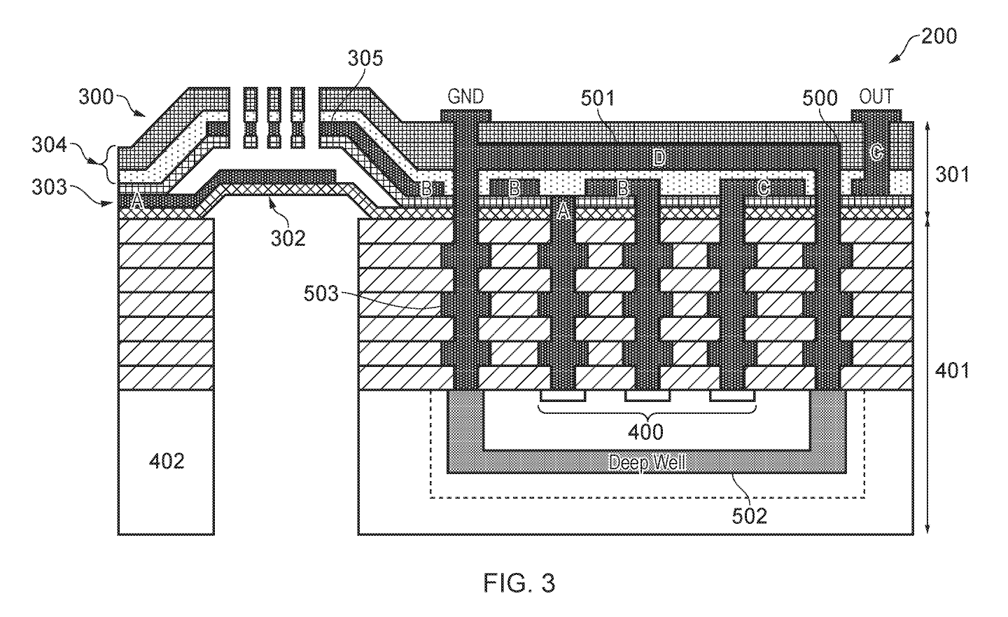

FIG. 3 shows an integrated MEMS transducer generally indicated 200 comprising a capacitive MEMS transducer structure 300, circuitry 400 and a conductive enclosure 500. The transducer 300 comprises a moveable membrane 302 having a membrane electrode 303 and a backplate 304 having an embedded backplate electrode 305. The transducer is formed in a first, transducer, region from a plurality of transducer layers or “MEMS” layers 301. The circuitry 400 is formed in a second, circuitry region from a plurality of CMOS layers 401 which are formed by depositing appropriate metal and inter-metal dielectric or inter-layer dielectric materials. In this example, the transducer layers 301 are formed on top of the CMOS layers 401. The circuitry and the MEMS transducer are provided on a substrate 402. In this example the substrate 402 can be considered to form one of the CMOS layers.

Membrane electrode 303 is routed via one or more electrical interconnects (not shown) and input to one or more of the circuitry components (for example, as referenced “A” in FIG. 3). Backplate electrode 305 is also routed via one or more electrical interconnects (not shown) and input to one or more of the circuitry components (for example, as referenced “B” in FIG. 3). One of the circuitry components is also routed to an output (as referenced “C” in FIG. 3). The enclosure 500, which acts as a Faraday cage for attenuating incident electromagnetic radiation, is preferably but not necessarily grounded (GND).

In this embodiment, the conductive enclosure 500 is formed from three key components, namely a conductive/metal top plate 501 (or “top”), a deep implant layer 502 (or “bottom”), and side walls 503 (or “side”), which connect the top plate 501 with the deep implant layer 502 to thereby provide a conductive enclosure around the circuitry. The top plate comprises a metal plate formed of at least one metal layer which is compatible with CMOS processing and which exhibits the required conductive properties for attenuating radiofrequency interference. For example, the top plate 501 may conveniently be formed of aluminium or copper.

In this example a deep implant layer forms a bottom plate 502 of the conductive enclosure 500. The deep implant layer is provided within the silicon substrate 402 and is formed by known means.

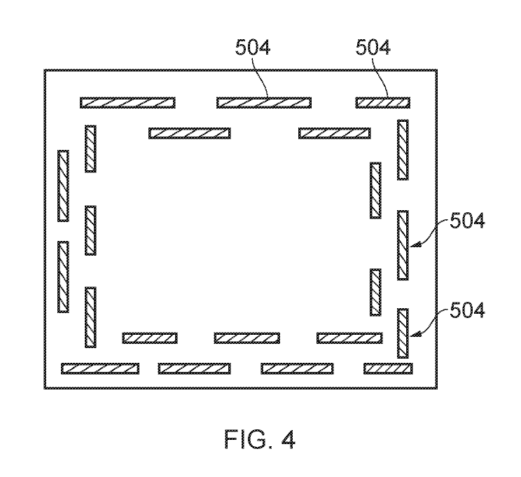

The side walls 503 are preferably formed from conductive vias. The formation of vias through the circuitry layers is achieved by etching holes through the stack of the circuitry layers and then filling the holes with a conductive material. The vias may be continuous trenches which substantially form a complete side wall of the enclosure. Alternatively, the vias may be discrete, preferably closely spaced, elements, or “castelattions”. FIG. 4 shows a cross-sectional view through the circuitry layers 401 in order to illustrate an offset repeating pattern of the vias 504 which facilitates electrical interconnection of the layers. In effect, the side walls can be considered to be a cage within a cage.

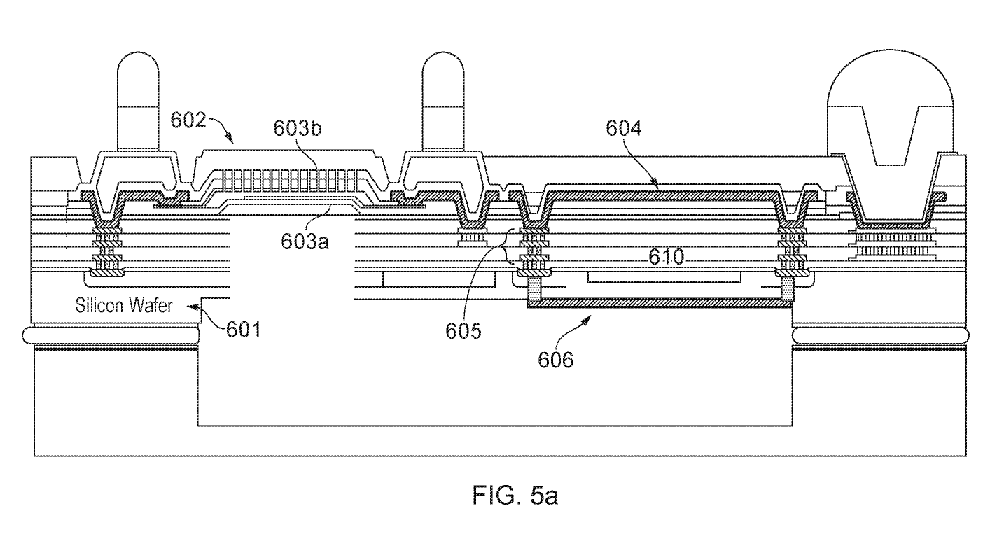

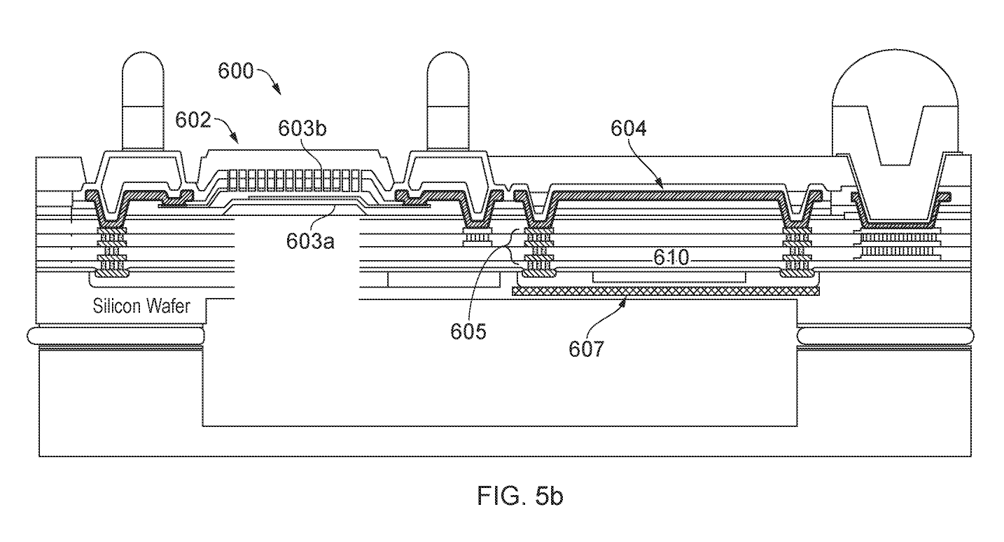

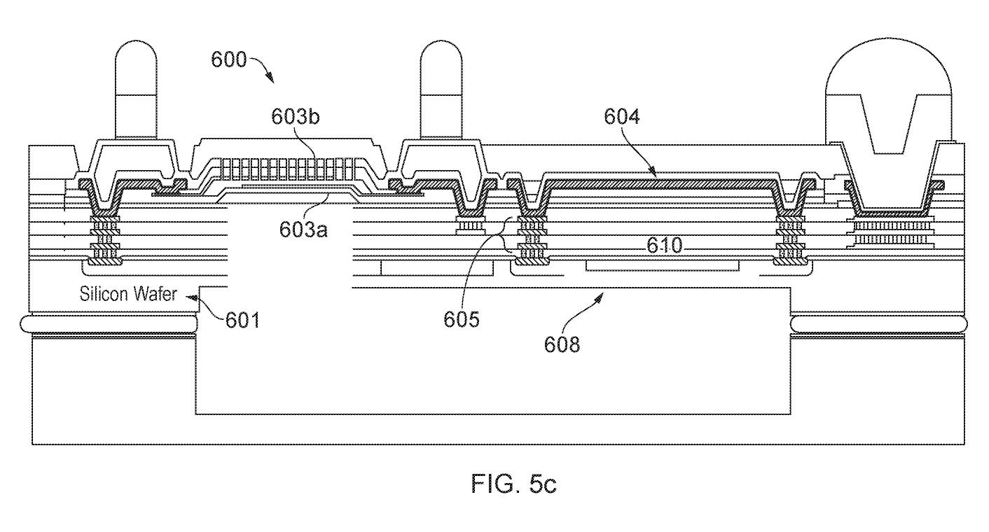

During fabrication of an integrated MEMS transducer having a conductive enclosure according to embodiments of the present invention, a suitable bottom-plate is formed prior to the deposition of the circuitry and transducer layers. The bottom-plate is formed so as to extend beneath the intended circuitry components formed from the CMOS layers. A number of possible bottom-plate designs may be employed within the scope of embodiments of the present invention which will be discussed with reference to FIGS. 5a to c.

Following the formation of the conductive back plate, the necessary CMOS circuitry is fabricated in the circuitry region using standard processing techniques that will be appreciated to those skilled in the art such as ion implantation, photomasking, metal deposition and etching. The circuitry may, without limitation, comprise some or all of amplifier circuitry, voltage biasing circuitry, filter circuitry, analogue to digital converters and/or digital to analogues converters, oscillator circuitry, voltage reference circuitry, current reference circuitry and charge pump circuitry. It will be appreciated that the circuitry layers will actually be varied across the circuitry region of the substrate to form distinct components and interconnections between components. The circuitry layers illustrated in FIG. 3, and in all the present examples, are for illustration purposes only.

Following the fabrication of the CMOS circuitry, a plurality of conductive vias are formed which connect the bottom plate with the intended top plate. Thus, the conductive vias form the side walls of the eventual conductive enclosure.

Once the CMOS layers have been fabricated the transducer layers are fabricated using techniques that will be known to those skilled in the art. Briefly, the fabrication of the membrane involves fabricating a membrane layer 302 comprising silicon nitride which is deposited using plasma enhanced chemical vapour deposition process to a thickness of about 0.4 μm for example. A membrane electrode layer is also deposited and patterned to form membrane electrode 303. The membrane electrode may comprise any suitable metal which is compatible with CMOS processing, such as aluminium, and may be deposited by sputtering. The thickness of the membrane electrode may be about 0.05 μm. Back plate layers are then deposited and may preferably comprise the same material as the membrane layer such as silicon nitride. Alternatively different materials may be used for one or more of the backplate layers if desired. The backplate electrode may be conveniently formed from the same metal as the membrane electrode, such as aluminium, and may be of the order of 1 μm thick.

According to embodiments of the present invention the metal top plate may be formed during one or more of the metallisation steps carried out as part of the formation of the transducer structure.

Thus, an advantage of embodiments of the present invention is that the enclosure 500 may be fabricated in parallel with the fabrication of the integrated MEMS transducer and circuitry using standard CMOS processing steps to form the elements of the enclosure. In other words, the production of the Faraday enclosure is merged with the production of the integrated MEMS transducer and may be conducted as a continuous process in a single standard CMOS foundry. Thus, the formation of the bottom-plate within, or on top of, the substrate is carried out prior to the deposition of the circuit layers. The via side walls are formed following the fabrication of the circuitry layers and prior to the formation of the transducer layers. Then, the metal top plate is formed, preferably by deposition, during the formation of the metal electrodes of the transducer layers. The method of the present invention therefore offers a truly CMOS process for the fabrication of integrated transducers incorporating a Faraday shield/enclosure.

FIGS. 5a to 5c show a cross section through an integrated MEMS transducer 600 formed on a silicon wafer 601 according to another embodiment of the present invention and illustrate three alternative bottom-plate designs. The MEMS transducer structure is generally designated 602 and includes a metal membrane electrode and a metal backplate electrode 603a and 603b. CMOS circuitry 610 is provided in a second, circuitry region, of the device. The circuitry is protected from EM interference by the provision of a conductive enclosure which is formed from a metal top-plate 604, a plurality of conductive vias forming side walls 605, and a bottom plate 606 which is configured to electrical connects the four side walls of the enclosure. In FIG. 5a the bottom-plate is formed of a metallisation layer 606 that is formed within the silicon wafer. In FIG. 5b the bottom-plate is formed of an extra-deep implant 607 that is formed within the silicon wafer. In FIG. 5c the bottom-plate is formed of a region of low-resistance silicon that underlies the CMOS circuitry 610. The top-plate 604 forms the top of the conductive enclosure and is comprised of a metalisation layer that is deposited during the deposition of metals layers required for the transducer structure—i.e. for the pair of electrodes and for providing an electrical connection between the transducer structure and the circuitry.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope.

1. An integrated MEMS transducer comprising a MEMS transducer structure and at least one circuit component, the integrated MEMS transducer further comprising a conductive enclosure provided such that the at least one circuit component is inside the conductive enclosure, and wherein the MEMS transducer structure is outside the enclosure.

2. An integrated MEMS transducer as claimed in claim 1, wherein the conductive enclosure comprises a top plate which overlies the circuitry.

3. An integrated MEMS transducer as claimed in claim 2, wherein the top plate is formed of material that forms at least a part of a layer of the transducer structure.

4. An integrated MEMS transducer as claimed in claim 1, wherein the conductive enclosure comprises a bottom plate that underlies the circuitry.

5. An integrated MEMS transducer as claimed in claim 1, wherein the conductive enclosure comprises at least one side wall formed of a plurality of conductive vias which extend through one or more layers of the integrated MEMS transducer.

6. An integrated MEMS transducer as claimed in claim 1, wherein the conductive enclosure comprises a top plate which overlies the circuitry and a bottom plate that underlies the circuitry, wherein the top plate and the bottom plate are connected by a plurality of conductive vias which extend through one or more layers of the integrated MEMS transducer to form side walls of the conductive enclosure.

7. An integrated MEMS transducer as claimed in claim 6, wherein the top plate comprises a conductive layer that also forms a layer of the MEMS transducer structure.

8. An integrated MEMS transducer as claimed in claim 4, wherein the bottom plate comprises at least one of an implant layer, a metal layer or a layer of low-resistance silicon.

9. An integrated MEMS transducer comprising a MEMS transducer structure and circuitry provided on a single substrate, wherein the MEMS transducer structure is formed from a plurality of transducer layers and wherein at least one conductive layer deposited during the fabrication of the MEMS transducer structure forms a shield which overlies the circuitry for shielding the circuitry from electromagnetic radiation.

10. An integrated MEMS transducer as claimed in claim 9, wherein the shield is electrically connected to a conductive layer which underlies the circuitry to form and electrically conductive enclosure around the circuitry.

11. An integrated MEMS transducer as claimed in claim 10, wherein the circuitry comprises a plurality of CMOS layers and further comprising a plurality of conductive vias which extend through one or more CMOS layers to form side walls of the conductive enclosure.

12. An integrated MEMS transducer as claimed claim 1, wherein the transducer structure comprises a capacitive MEMS transducer comprising a moveable membrane having a membrane electrode and a back-plate having a back-plate electrode.

13. A MEMS transducer package comprising an integrated MEMS transducer as claimed in claim 1, further comprising a package cover which overlies the integrated MEMS transducer.

14. A MEMS transducer package as claimed in claim 13 comprising a package substrate which is electrically connected to the substrate of the integrated MEMS transducer.

15. A method of fabricating an integrated MEMS transducer comprising a MEMS transducer structure and at least one circuit component on a substrate, the method comprising:
forming, on a first region of the substrate, a plurality of CMOS layers, wherein the at least one circuit component is formed from one or more of the CMOS layers;
forming, on a second region of the substrate, a plurality of transducer layers to form the MEMS transducer structure;
wherein said method comprises depositing conductive material which forms a conductive layer of the MEMS transducer structure and which also forms a top-plate which overlies the at least one circuit component, said top-plate being for shielding the circuitry from electromagnetic radiation.

16. A method as claimed in claim 15, further comprising forming a plurality of conductive vias which extend through one or more of the CMOS layers to connect the top-plate to a bottom plate which is formed beneath the at least one circuit component.

17. A method as claimed in claim 15, wherein the common layer of conductive material forms a layer of a backplate of the MEMS transducer structure.

18. A method as claimed in claim 15, wherein the step of forming a plurality of transducer layers comprises forming a plurality of back-plate layers, at least one sacrificial structure and at least one membrane layer such that removal of the at least one sacrificial structure results in a moveable membrane and a rigid back plate.

19. A method as claimed in claim 18, further comprising depositing at least one metal layer to form a membrane electrode and at least one metal layer to form a back-plate electrode.

20. A method as claimed in claim 19, further comprising:
forming an electrical connection between the membrane electrode and one said circuit component; and
forming an electrical connection between the backplate electrode and one said circuit component.
